(19) United States
(12) Patent Application Publication
(10) Pub. No.: US 2012/0171848 A1
(43) Pub. Date: Jul. 5, 2012

(54) Method and System for Manufacturing Silicon and Silicon Carbide

(75) Inventor: Takashi TOMITA, Nara-shi (JP)

(73) Assignee: Takashi Tomita, Nara-shi (JP)

(21) Appl. No.: 13/351,638

(22) Filed: Jan. 17, 2012

Related U.S. Application Data
(62) Division of application No. 13/079,996, filed on Apr. 5, 2011.

(30) Foreign Application Priority Data
Apr. 6, 2010 (JP) 2010-088015

(51) Int. Cl. H01L 21/20; B01J 19/00

(52) U.S. Cl. 438/478; 422/198; 257/E21.09

(57) ABSTRACT

The present invention provides a method of manufacturing silicon and a manufacturing system for manufacturing and extracting silicon by grinding silicon carbide and silica, mixing each at predetermined ratio after cleaning them, housing them in a crucible, heating this by a heating unit to make them react, oxidizing the silicon carbide with the silica and further, reducing the silica with the silicon carbide. The present invention further provides a method of simultaneously manufacturing silicon and silicon carbide and a manufacturing system for producing silicon carbide by forming a silicon carbide film by vapor phase epitaxy using active gas generated in heating for reaction for material and recovering the silicon carbide film.

### CROSS-REFERENCE TO RELATED APPLICATIONS

This application is a division of U.S. Application Ser. No. 13/079,996, filed Apr. 5, 2011, which claims priority under 35 U.S.C. §119 to Japanese Patent Application No. 2010-088015, filed Apr. 6, 2010, the entire disclosure of which is herein expressly incorporated by reference.

### BACKGROUND OF THE INVENTION

(1) Field of the Invention

The present invention relates to a method and a system for manufacturing materials of silicon and silicon carbide used for a semiconductor, a solar cell and others.

(2) Description of the Related Art

The present invention particularly relates to a method of reducing and manufacturing silicon for a high-purity semiconductor and a solar cell. For silicon manufacturing technology, heretofore, a method of generally using an arc furnace, individually putting carbon coke and silica rock (or silica sand) respectively as material into the furnace or mixing them and putting them into the furnace, supplying electrical energy from a carbon electrode installed with the carbon electrode hung from the upside, reducing silica and purifying silicon was used. This reactional process is mostly clarified and silicon generated by reaction in a dome including silica, carbon and fractional silicon carbide is extracted.

Normal silicon manufactured in the above-mentioned process shows no semiconductor characteristic, is called metal silicon (MG-Si), and is produced in large quantities. This cause is that a large quantity of impurities mix in the silicon. It is known that the impurities are boron, phosphorus, aluminum, iron, manganese-titanium and others.

### SUMMARY OF THE INVENTION

It is known that these impurities result from impurities mainly included in silica rock (silica sand) and carbon coke. However, researches by these inventors tell that much impurities also mix from the carbon electrode, materials of the furnace and a crucible for tapping respectively for causing reaction in the arc furnace. As the carbon electrode for supplying electric power, coke and silica rock as material are put from an upper part of the furnace because of the structure of the arc furnace, impurities the vapor pressure of which is high are vaporized, however, elements such as iron and nickel the vapor pressure of which is low from the carbon electrode, the coke and the silica rock as material are gradually concentrated and are incorporated into metal silicon. It is clarified that though phosphorus and others the vapor pressure of which is high are once vaporized in reaction, they adhere to an area the temperature of which is low of the arc furnace and are restored to original materials again.

An extremely important condition for silicon used for a semiconductor is that few impurities are included. To secure high purity, a leaching method is taken by mixing calcium carbonate in metal silicon further remelted, dissolving calcium silicate hereby produced with acid, dissolving and removing impurities absorbed in the calcium silicate. The degree of impurities as a result is equivalent to approximately 1 to 3 N at most and no semiconductor characteristic is shown likewise. Then, heretofore, a method (Siemens method) was used by dissolving and vaporizing silicon with high-temperature hydrochloric acid and others, manufacturing silicon tetrachloride or silicon trichloride, distilling and purifying this many times, manufacturing high-purity silicon tetrachloride or high-purity silicon trichloride, further, thermally decomposing this by an electrified silicon filament and facilitating the vapor phase epitaxy of silicon. As a result, much electrical energy was consumed. Or a metallurgical process was utilized by oxidizing the metal silicon with vaporous plasma and removing boron, holding the metal silicon in a vacuum and removing phosphorus, finally slowly cooling the metal silicon by one-way freezing and segregating impurities such as iron and nickel.

A cause in which impurities are incorporated into silicon purified in the arc furnace is that not only impurities included in silica rock and coke as material but impurities in a furnace wall and the carbon electrode mix in silicon which is a product. As for the silica rock and the coke, high-purity those can be selected before usage and the cost is naturally increased, however, when those are ground into fine particles in which sufficient cleaning effect is acquired, it is difficult to put materials themselves into the arc furnace in which strong convection is caused. Besides, there is a case that a metallic component such as iron is intentionally mixed particularly in carbon for the electrode to prevent breakage in usage at high temperature and the impurity is incorporated in silicon.

To smoothly reduce efficiently for input electric power, a condition in which slightly much oxygen is included is desirable and as silicon monoxide likewise gaseous is emitted when carbon monoxide generated in a reactional process is emitted from the furnace, the silicon monoxide is oxidized outside the furnace and is restored to silicon dioxide again. As this rate accounts for 20 to 30% in normal commercial production, a heat recovery system is required in addition to recovery and removal by a bag filter and the amount for plant and equipment investment is increased.

The arc furnace is normally open, however, as convection is caused, fine particles cannot be used in the supply of materials such as coke and silica rock and only solid material of dimensions to some extent can be put. Therefore, impurities included in the solid material cannot be easily removed. Besides, generated silicon is required to be not continuously but intermittently extracted.

The above-mentioned leaching method has waste such as high-purity calcium carbonate is required, energy for remelting silicon is required, further, grinding silicon, dissolving and removing calcium silicate with acid are required, electrical energy is required, further, silicon is lost and in addition, acid and the materials of calcium carbonate are required.

In the meantime, the Siemens method has an advantage that included impurities can be reduced to degree equivalent to approximately 9 to 11 N like silane tetrachloride and silane trichloride and silicon can be highly purified, however, the Siemens method has a problem that silicon is expensive because a large amount of costs for facilities are required for using chlorine and a large quantity of electrical energy is required for vapor phase epitaxy.

The present invention is made in view of the above-mentioned problems. FIG. 1 is a schematic diagram for explaining the principle of a method of manufacturing silicon and silicon carbide according to the present invention. Carbon coke (51) and silica sand (silica) (52) as material are ground in approximate few mm or less beforehand. These are cleaned with aqueous solution including acid or alkali, and impurities the vapor pressure of which is low and moisture are removed. After coke (1) and silica (2) respectively prepared as described above are kneaded (53) at predetermined ratio, they are heated up to 1500 to 3000 degrees and silicon carbide (54) as an intermediate product is once manufactured. For a heating method, resistance heating is used. However, a device that carrier gas is shed is required to prevent nitrogen in air from being incorporated into the silicon carbide. In this process, effect that impurities the vapor pressure of which is high are removed can be also enhanced.

The silicon carbide (54) which is the intermediate product is ground, the ground silicon carbide (4) is mixed with high-purity silica manufactured by the above-mentioned method, the ground silicon carbide and the silica are heated at 1500 to 2000 degrees in a high frequency induction furnace (7) to make them react, and silicon fused liquid (55) is extracted. The silicon fused liquid can be crystallized by various methods.

A method of manufacturing silicon according to the present invention has the steps such that silicon carbide and silica sand (silica) are ground, silicon carbide and silica sand (silica) are mixed with each other at predetermined ratio after cleaning them, the silicon carbide and the silica sand (the silica) are housed in a crucible for heating, they are heated by heating means to make them react, the silicon carbide is oxidized with the silica sand (the silica), and further, the silica sand (the silica) is reduced with the silicon carbide to manufacture and extract silicon.

In the method of manufacturing silicon, the degree of impurities of the silicon carbide is equivalent to high purity of 3 N or more and the degree of impurities in the silica sand is equivalent to high purity of 3 N or more.

In the method of manufacturing silicon, the heating means is high-frequency induction heating.

In the method of manufacturing silicon, the heating means is direct current resistance heating.

In the method of manufacturing silicon, the crucible for heating is made of silicon carbide.

A method of manufacturing a silicon carbide semiconductor according to the present invention based upon a silicon manufacturing method of manufacturing and extracting silicon by: mixing silicon carbide and silica sand (silica) with each other at predetermined ratio after silicon carbide and silica sand (silica) are ground and are cleaned; housing the silicon carbide and the silica sand (the silica) in a crucible; heating this by heating means to make them react; oxidizing the silicon carbide with the silica sand (the silica); and further reducing the silica sand (the silica) with the silicon carbide, has the steps such that a silicon carbide film is formed by vapor phase epitaxy using active gas generated in heating for reaction for material, and is recovered.

A method of manufacturing a silicon carbide semiconductor according to the present invention based upon a method of manufacturing and extracting silicon by: grinding silicon carbide and silica sand (silica); mixing each at predetermined ratio after cleaning them; housing them in a crucible for heating; heating this by heating means to make them react; oxidizing the silicon carbide with the silica sand (the silica); and further reducing the silica sand (the silica) with the silicon carbide, has the steps such that carbon in silicon is held in a condition of supersaturation by absorbing carbon from carbon monoxide and silicon from silicon monoxide in silicon fused liquid separately prepared using the carbon monoxide and the silicon monoxide in active gas generated in heating for material, a silicon carbide film is formed by slowly cooling and facilitating epitaxial growth and is recovered.

In the method of manufacturing a silicon carbide semiconductor, the crucible for heating is made of silicon carbide.

In the method of manufacturing silicon, in heating for reaction, the crucible for heating is housed in a bell jar to enable reaction in a decompressed condition.

In the method of manufacturing a silicon carbide semiconductor, in heating for reaction, the crucible for heating is housed in a bell jar to enable reaction in a decompressed condition.

In the method of manufacturing silicon, the ratio of silicon carbide to silica sand (silica) is mainly 1:1, 10:1 may be also at the maximum and 1:10 may be also at the minimum.

In the method of manufacturing a silicon carbide semiconductor, the ratio of silicon carbide to silica sand (silica) is mainly 1:1, 10:1 may be also at the maximum and 1:10 may be also at the minimum.

In the method of manufacturing silicon, the crucible for heating is housed in the bell jar to enable reaction in inert gas.

In the method of manufacturing a silicon carbide semiconductor, the crucible for heating is housed in the bell jar for heating in inert gas.

In the method of manufacturing silicon, a crucible for recovery, the crucible for heating and a crucible for extraction are provided, the crucibles are formed in a cascaded configuration and are housed in the bell jar to facilitate reaction by heating.

In the method of manufacturing silicon, a crucible for recovery, the crucible for heating and a crucible for extraction are provided, the crucible for heating and the crucible for extraction are formed in a cascaded configuration, the crucible for recovery is installed sideways alongside the crucible for heating, the crucible for recovery is formed so that a lateral dimension is longer and they are housed in the bell jar to facilitate reaction by heating.

In the method of manufacturing a silicon carbide semiconductor, a crucible for recovery, the crucible for heating and a crucible for extraction are provided, the crucible for heating and the crucible for extraction are formed in a cascaded configuration, the crucible for recovery is installed sideways alongside the crucible for heating, the crucible for recovery is formed so that a lateral dimension is longer and they are housed in the bell jar to facilitate reaction by heating.

A method of manufacturing silicon for simultaneously manufacturing silicon and silicon carbide based upon a method of manufacturing and extracting silicon by: grinding silicon carbide and silica sand (silica); mixing silicon carbide and silica sand (silica) with each other at predetermined ratio after cleaning them; housing them in a crucible for heating; heating this by heating means to make them react; oxidizing the silicon carbide with the silica sand (the silica); and further reducing the silica sand (the silica) with the silicon carbide, has the steps such that a silicon carbide film is formed by vapor phase epitaxy using active gas generated in heating for reaction for material, and silicon carbide is produced by recovering the silicon carbide film.

A method of manufacturing silicon for simultaneously manufacturing silicon and silicon carbide based upon a method of manufacturing and extracting silicon by: grinding silicon carbide and silica sand (silica); mixing silicon carbide and silica sand (silica) at predetermined ratio after cleaning them; housing them in a crucible for heating; heating this by heating means to make them react; oxidizing the silicon carbide with the silica sand (the silica); and further reducing the silica sand (the silica) with the silicon carbide, has the steps such that carbon in silicon is held in a condition of supersaturation by absorbing carbon from carbon monoxide and silicon from silicon monoxide in silicon fused liquid separately prepared using carbon monoxide and silicon monoxide in active gas generated in heating for material, a silicon carbide film is formed by epitaxial growth by slowly cooling, and silicon carbide is produced by recovering the silicon carbide film.

In the method of manufacturing silicon, a crucible for recovery, a crucible for heating and a crucible for extraction are provided, the crucible for heating and the crucible for extraction are formed in a cascaded configuration, the crucible for recovery is installed sideways alongside the crucible for heating, the crucible for recovery is formed so that a lateral dimension is longer, and silicon and silicon carbide are simultaneously manufactured by housing them in a bell jar to facilitate reaction by heating.

A silicon manufacturing system according to the present invention is provided with a crucible for heating that houses silicon carbide and silica sand (silica) respectively ground, cleaned and mixed, heating means that heats this and a crucible for extraction that houses silicon extracted by oxidizing the silicon carbide with the silica sand (the silica) and further, reducing the silica sand (the silica) with the silicon carbide.

A silicon carbide semiconductor manufacturing system according to the present invention is provided with a crucible for heating that houses silicon carbide and silica sand (silica) respectively ground, cleaned and mixed, heating means that heats this, a crucible for extraction that houses silicon extracted by oxidizing the silicon carbide with the silica sand (the silica) and further, reducing the silica sand (the silica) with the silicon carbide, recovering means that recovers active gas generated in heating for reaction, and a crucible for recovery that recovers a silicon carbide film formed by using active gas generated in heating for reaction for material.

In the silicon manufacturing system, a crucible for recovery, the crucible for heating and the crucible for extraction are provided, the crucibles are formed in a cascaded configuration, decompressing means is provided, and the crucibles and the decompressing means are housed in a bell jar.

In the silicon manufacturing system, a crucible for recovery, the crucible for heating and the crucible for extraction are provided, the crucible for heating and the crucible for extraction are formed in a cascaded configuration, the crucible for recovery is installed sideways alongside the crucible for heating, the crucible for recovery is formed so that a lateral dimension is longer, decompressing means is provided, and the crucibles and the decompressing means are housed in a bell jar.

In the silicon carbide semiconductor manufacturing system, the crucible for recovery, the crucible for heating and the crucible for extraction are provided, the crucibles are formed in a cascaded configuration, decompressing means is provided, and the crucibles and the decompressing means are housed in a bell jar.

In the silicon carbide semiconductor manufacturing system, the crucible for recovery, the crucible for heating and the crucible for extraction are provided, the crucible for heating and the crucible for extraction are formed in a cascaded configuration, the crucible for recovery is installed sideways alongside the crucible for heating, the crucible for recovery is formed so that a lateral dimension is longer, decompressing means is provided, and the crucibles and the decompressing means are housed in a bell jar.

In the silicon manufacturing system, the ratio of silicon carbide to silica sand (silica) is 2:1.

In the silicon carbide semiconductor manufacturing system, the ratio of silicon carbide to silica sand (silica) is 2:1.

In the method of manufacturing silicon, heating is performed to cause reaction in a condition in which an atmosphere is decompressed from 1 to 0.01 Pa.

In the method of manufacturing a silicon carbide semiconductor, heating is performed to cause reaction in a condition in which an atmosphere is decompressed from 1 to 0.01 Pa.

FIGS. 2A and 2B are schematic diagrams for explaining the operation of a reactor according to the present invention.

As shown in FIG. 1, for reaction products in the above-mentioned reactional process, carbon monoxide (56) and silicon monoxide (57) are generated, however, they are led into a container (10) separately prepared, and thermal energy and the materials are recovered. For reaction products in the reactional process, SiO gas and carbon monoxide (CO) are dissolved by a microwave or induction heating, and the recovery of silicon and carbon can be accelerated. To recover these, silicon fused liquid (58) is used.

Besides, carbon monoxide (56) and silicon monoxide (57) purified in a reducing process are exhausted in the shape of coke held at high temperature, however, the silicon monoxide (57) reacts with carbon, and a silicon carbide film is generated.

To replenish materials, carbon coke (50) may be also added.

The silicon carbide film not only can be used for material for purifying silicon but can epitaxially grow silicon carbide (11) for a semiconductor using carbon, silicon or silicon carbide or sapphire for a substrate.

To use silicon for a semiconductor, the content of impurities is turned to a sufficiently low content and the content can be enhanced to a high level equivalent to 6 to 11 N. Besides, energy and materials can be greatly saved. Further, the high-purity silicon carbide film can be grown.

For the heating means, induction heating is described, however, it need scarcely be said that another electric resistance heating can be adopted.

Silicon (55) can be stably and continuously purified by using silicon carbide (54) and silica (52) for material, applying energy by an electromagnetic field or a microwave and producing a condition shielded from the air. Silicon (55) generated by the method has extremely high purity and quality equivalent to a grade of a semiconductor can be secured.

As carbon monoxide finally generated can be continuously extracted outdoors and in addition, can be used for the preheating of materials, cleaning and purifying material coke and material silica because heat is further generated in a combustion process of the carbon monoxide, the waste of energy and materials is reduced and silicon carbide can be extracted.

### BRIEF DESCRIPTION OF THE DRAWINGS

Embodiments of the present invention will be described in detail based on the following drawings, wherein:

FIG. 1 is a schematic diagram for explaining the principle of a method of manufacturing silicon and silicon carbide according to the present invention;

FIGS. 2A and 2B are schematic diagrams showing an induction heating reactor according to the present invention, FIG. 2A is the schematic diagram for illustrating the structure, and FIG. 2B is the schematic diagram for explaining temperature distribution;

FIG. 3 is a schematic diagram for illustrating the configuration of an induction heating reactor according to the present invention;

FIG. 4 is a schematic diagram for illustrating the configuration of an induction heating reactor according to the present invention; and

FIG. 5 shows silicon produced by an induction heating reactor according to the present invention.

### DETAILED DESCRIPTION OF THE INVENTION

### First Embodiment

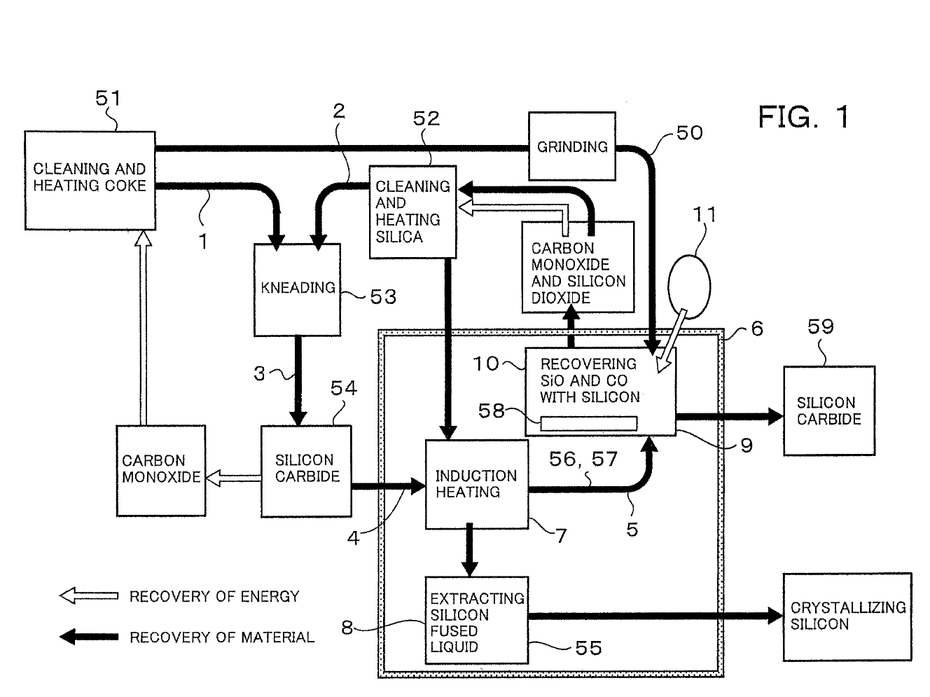

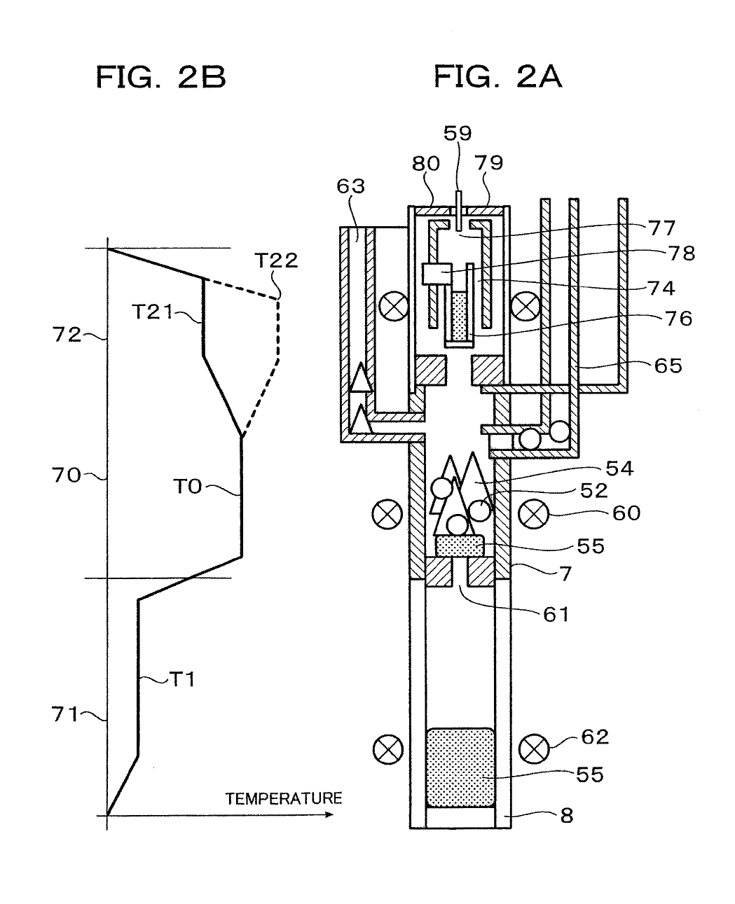

FIG. 1 is a schematic diagram for explaining the principle of a method of manufacturing silicon and silicon carbide according to the present invention. FIGS. 2A and 2B are schematic diagrams for illustrating an induction heating reactor used in the present invention.

Table 1 shows each content of boron, phosphorus, calcium, titanium, iron, nickel and copper which are respectively impurities in coke as material, cleaned coke, silica as material, cleaned silica, silicon carbide and silicon in units of ppm.

TABLE 1
Impurities Analysis

| | Material | Cleaned | Material | Cleaned | | Silicon | | |
|---|---|---|---|---|---|---|---|---|
| | coke | coke | silica | silica | | carbide | | Silicon |
| Boron | 8 | 0.2 | 5 | 0.1 | | <0.05 | | <0.05 |
| Phosphorus | 20 | 1 | 1 | 0.1 | | <0.05 | | <0.05 |
| Calcium | 10 | 1 | 30 | 1 | 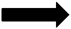 | <0.05 | 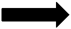 | <0.05 |
| Titanium | 3 | 0.05 | 40 | 0.1 | | <0.05 | | <0.05 |
| Iron | 20 | 0.5 | 10 | 0.5 | | <0.05 | | <0.05 |
| Nickel | 10 | 0.5 | 5 | 0.5 | | <0.05 | | <0.05 |
| Copper | 10 | 0.5 | 10 | 0.5 | | <0.05 | | <0.05 |

Coke as material (51) is ground in units of mm beforehand. Table 1 shows results of analyzing impurities in the carbon coke.

The coke as material is cleaned with aqueous solution. For a clearing solvent, HCN of 0.1 mol is used. After cleaning, the coke is dried at the temperature of 600 to 1200° C. In drying, the impurities the vapor pressure of which is high are desorbed and removed from the coke (a step 1).

Silica as material (52) is ground in units of mm beforehand. Table 1 shows results of analyzing impurities in the silica.

The silica is cleaned with aqueous solution, is heated and is dried.

For a clearing solvent, HCN of 0.1 mol is used (a step 2).

For the clearing solvent, nitric acid, hydrochloric acid and hydrofluoric acid can be also applied in addition to the HCN. The concentration and the pH are not basically relevant to basic action though the reaction time varies depending upon them. Table 1 shows results of analyzing the impurities after cleaning.

Material (53) acquired by mixing and kneading the silica as material and the coke as material respectively prepared in the steps at the ratio of 1:1 to 1:3 is dried. Silicon carbide which is an intermediate product is manufactured by heating the dried material to activate it. To facilitate the reaction, high temperature of 1500 to 2500° C. is required and for a heating method in the present invention, a resistance heating method is used. For heating temperature, 1500 to 3000 degrees are desirable. The sublimation of impurities is facilitated by making the dried material react at the high temperature (a step 3).

In the heating step to activate, carbon monoxide and silicon monoxide are generated, however, the temperature of a reactant by heating can be raised up to temperature equal to or exceeding 1500 degrees by oxidizing the dried material in an oxygen atmosphere. A reactional process is approximately 10 to 100 hours. Table 1 shows results of analyzing impurities in silicon carbide in this case.

For heating means, any of a heliostat, a heating method by energizing, a microwave and induction heating can be applied.

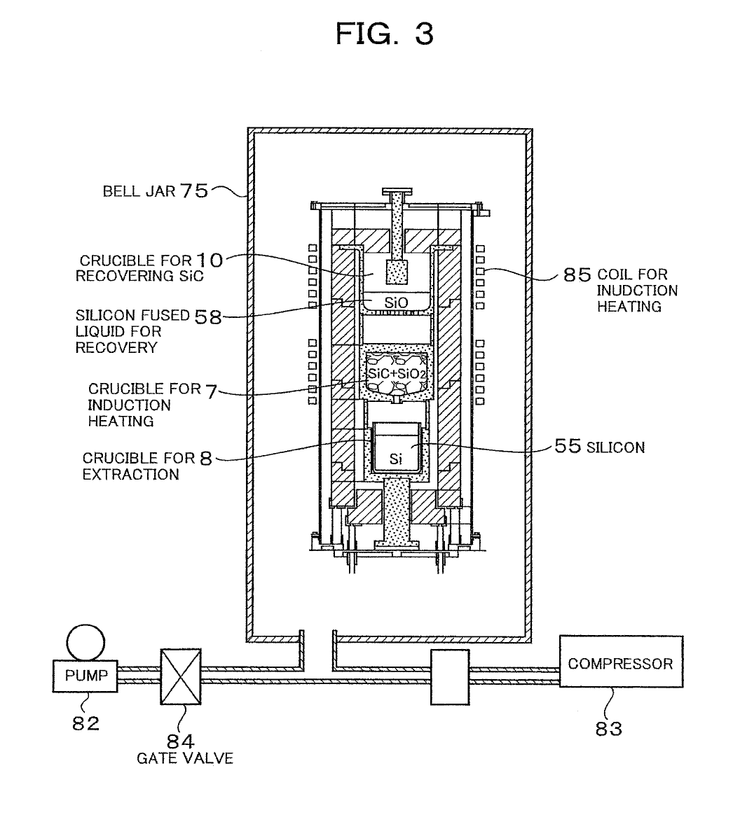

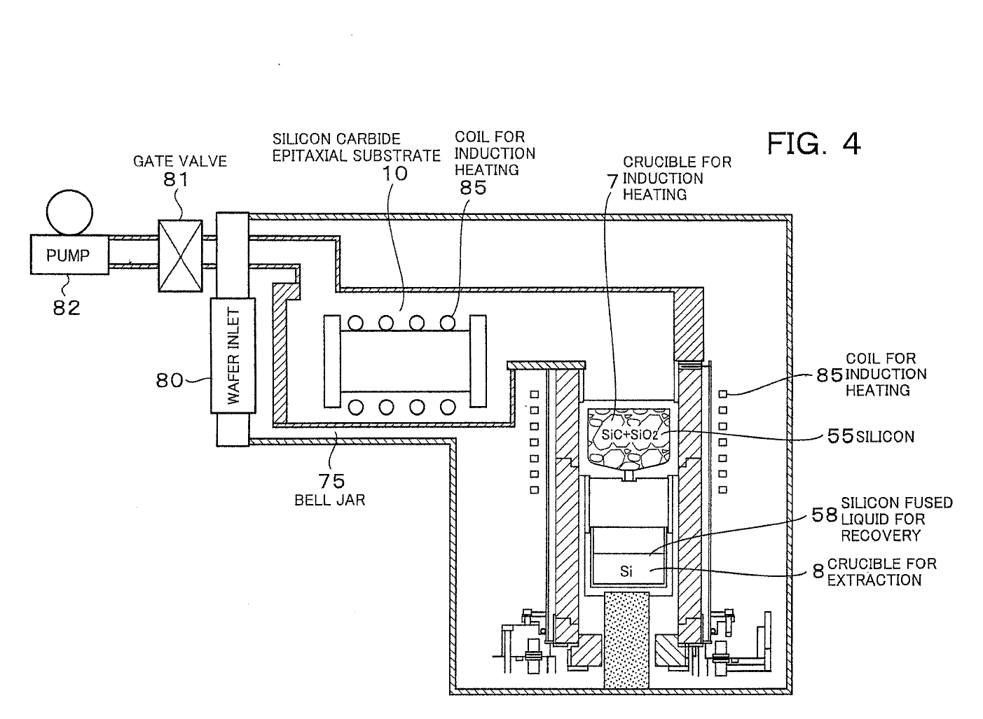

FIGS. 2A and 2B are the schematic diagrams for illustrating the induction heating reactor according to the present invention, FIG. 2A is the schematic diagram for illustrating the structure, and FIG. 2B is the schematic diagram for explaining the temperature distribution. FIG. 3 is a schematic diagram for illustrating the configuration of the induction heating reactor according to the present invention and FIG. 4 is a schematic diagram for illustrating the configuration of another induction heating reactor according to the present invention.

The silicon carbide (54) produced in the above-mentioned reactional step is ground (a step 4), is mixed with the silica, and is heated up to 1500 to 2500° C. in the multistage reactor (6) by an induction heating method. In the reactor, the silica and the silicon carbide mutually react, and silicon, carbon monoxide and silicon monoxide are generated. As the silicon (55) is turned into fused liquid, it drips from a crucible for heating (7) and is stored in a crucible for extraction (8). The silicon is at a level that only extremely few impurities are included. The silicon (55) of 28 g can be extracted for the input total 94 g of the silicon carbide and the silica. The reaction is controlled depending upon the quantity of the silicon carbide. Table 1 shows results of analyzing impurities in the silicon according to ICP. As a result, a high purity semiconductor can be acquired. In the reactor according to the present invention, for the ratio of the silicon carbide to the silica, 2:1 is optimum.

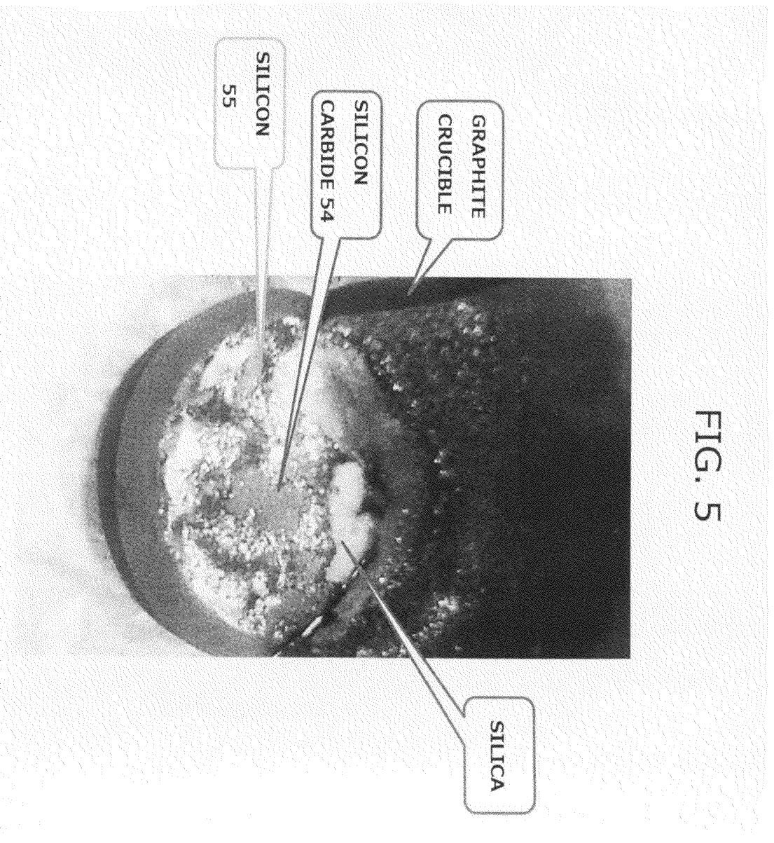

FIG. 5 is a picture showing the silicon manufactured according to the embodiment of the present invention. In the graphite crucible, the silicon (55), the silicon carbide (54) and the silica are produced.

As shown in FIG. 1, the carbon monoxide (56) and the silicon monoxide (57) are put into the silicon fused liquid (58) in a crucible for recovery (9) with the heat of the carbon monoxide and the silicon monoxide insulated. The carbon monoxide is dissolved in the silicon fused liquid and carbon is eluted. The silicon monoxide is dissolved into silicon dioxide and silicon. Silicon of approximately 50% is recovered. The recovery of reacted gas is more facilitated by high-frequency induction heating and decompression. In this embodiment, an atmosphere is decompressed from 1 to 0.01 Pa.

When a silicon carbide substrate (11) is put into the crucible for recovery (9), the thickness of the substrate is increased from initial 0.25 mm to 0.35 mm and epitaxial growth is enabled at 1800 degrees. For a growth rate, as the temperature rises in a range of 1500 to 2000° C., the substrate can be thickened and in addition, silicon carbide (59) can be recovered from exhaust gas. The diameter of the crucible for recovery (9) is set to 6 inches for enabling fully housing a wafer substrate having a diameter of 4 inches. The recovery of the carbon monoxide is more facilitated by extending the caliber of the crucible for recovery (9). This reason is that the solubility of carbon in silicon increases. In this case, when ground coke is further added to the silicon fused liquid by predetermined quantity, the growth rate can be more accelerated.

Silicon dioxide (silica) exhausted from the crucible for recovery (9) is restored to silica (51) though it is in a minute particle. At this time, waste heat and the material can be recovered. In the embodiment shown in FIG. 2, the reactor is formed in a vertical type, however, to enhance productivity and workability, the reactor may be also formed in a horizontal type.

### Second Embodiment

A second embodiment relates to configuration for integrating the above-mentioned reactional process so as to enhance efficiency in utilizing input energy. As shown in FIG. 2A, a basic process is the same as the basic process in the first embodiment and continuous production is aimed at. Heating is made using a coil (60) for induction heating according to a high-frequency induction method. Silicon carbide (54) is put into a crucible for heating (7) via a conduit tube (63). Silica (52) is put from the crucible for heating (7) through a conduit tube (65) into a silicon holding/solidifying crucible (8) through a silicon extracting hole (61). Hereby, silicon (55) is recovered.

The above-mentioned reactor is controlled to be temperature distribution at three stages. FIG. 2B shows the temperature distribution. An uppermost stage is equivalent to a reactor for growing silicon carbide (9) and the temperature (T2) is 1500 to 2500° C. A middle stage is equivalent to the crucible (7) for heating silicon carbide and silica respectively as material and the temperature is T0. In this area, silicon, SiO and carbon monoxide are manufactured. For the material of an external wall, carbonaceous material is used and an induction heating system is used for a heating method. Inside the external wall, the crucible for carbon or silicon carbide and silica is arranged. It is effective so as to reduce the wastage of the carbonaceous material of the crucible that quartz or a ceramic is further applied to the outside of the material of the external wall. The hole (61) for extracting a silicon product is formed at the bottom of the crucible.

The silicon (55) extracted through the extracting hole (61) flows into a crucible for extraction at the lowermost stage of the reactor. It is effective so as to more efficiently remove unnecessary carbon and unnecessary silicon carbide that an atmosphere at the lowermost stage is made oxidative. The temperature (T1) is controlled at 1450° C. The silicon once stored in the crucible for extraction can be continuously produced by being led into the solidifying crucible via a lead-through tube. For a solidifying method, any of Czochralski method, a solidifying process and a rotating solidifying process may be used. The content of oxygen is controlled to be 10 to 0.01%. The solubility of carbon can be reduced by keeping in oxidative atmosphere. As the crucible is installed in a lowermost area (71) of the reactor, purified and output silicon fused liquid is gradually solidified directly and can be extracted in the shape of an ingot. To realize it, for a method of keeping heat at T2, not only high-frequency induction heating but resistance heating can be applied.

An uppermost area (72) of the reactor is used for the growth of silicon carbide. A gate window is provided between the uppermost area (72) and a middle area (70) and the gate window is designed to enable a flow of gas which is a mixture of SiO and CO from the middle stage. At the uppermost stage, a crucible (74) is arranged. For the materials of the crucible (74), silicon carbide and fused quartz can be used. In this embodiment, its external wall is made of carbon and the inside is made of silicon carbide or magnesium oxide or alumina. Inside the crucible (74), fused silicon (76) is held. A surface of the silicon is normally exposed to SiO and CO. As a result, CO is dissolved into the silicon. As a result, a part of the silicon is vaporized as SiO, however, SiO mutually reacts, and is separated into silicon and silica.

The silica is deposited on the upside of the silicon, however, a hole for putting carbon (77) is provided and the silica can be replenished in silicon fused liquid. A silica removal jig (78) is equipped to remove the silica formed on the surface of the silicon (76) by a mechanical method. A wafer inlet (80) is provided for putting a silicon carbide wafer through a lid (79) installed in an upper part, facilitating epitaxial growth and extracting it again. The temperature is raised from T21 to T22, the solubility of carbon in the silicon is enhanced to saturated solubility, silicon carbide (59) is deposited on an epitaxial substrate (11), while slowly cooling to be T21, the temperature is raised again after epitaxy, and carbon is replenished. For the substrate, graphite and silicon carbide can be used. The silicon carbide can be continuously grown by repeating this operation (see FIG. 2).

As shown in FIGS. 3 and 4, the loss of silicon by the mixture of oxygen and the incorporation of impurities into silicon carbide by the mixture of nitrogen can be inhibited by housing the whole multistage furnace in a container called a bell jar (75) and exhausting air by an arranged pump (82). In this case, a compressor (83) and gate valves (81), (84) are provided.

Besides, the rate of reaction between silicon carbide and silica which are intermediate products can be controlled by filling with inert gas such as argon and further, controlling a condition of pressure. The velocity of the generation of silicon is gradually accelerated by decompressing from 1 to 0.01 Pa and the velocity of the generation of silicon can be gradually inhibited by pressurizing from 1 to 5 Pa.

### Third Embodiment

In the above-mentioned embodiments, the multistage furnace in which the reactors are vertically arranged is used, however, as reactive gas is caused vigorously upward in the reactor at the uppermost stage, the surface of the wafer may be covered with silica when the wafer for recovering silicon carbide is put. To address this problem, a multistage furnace in which reactors are laterally arranged is provided. FIG. 4 shows the multistage furnace in the third embodiment. Carbon monoxide and silicon monoxide respectively caused from a crucible for heating (7) are laterally led. A surface of an input wafer can be prevented from being covered with silica by laterally arranging the reactor. Besides, as the reactor is laterally extended, more carbon monoxide and more silicon monoxide can be recovered.

For heating means, induction heating is used, however, it need scarcely be said that means such as electric resistance heating can be adopted.

In the present invention, high-purity silicon can be easily extracted without passing many steps, compared with the related art. Besides, as the temperature of the generation can be lowered, energy can be saved. When impurities once mix in silicon, a great deal of energy is required, however, in the present invention, as impurities can be simultaneously removed in manufacturing silicon carbide which is the intermediate product from materials from which impurities are removed beforehand, the mixture of impurities can be also inhibited when silicon is generated.

In the present invention, in addition to the above-mentioned effects, as reactive gas can be recovered in the shape of silicon carbide and the silicon carbide can be recovered at high speed and effectively in the shape of the wafer utilizable as an electronic device in the recovery, the loss of the materials can be reduced. The present invention can greatly contribute to new silicon manufacturing technology.

What is claimed is:

1. A method of manufacturing a silicon carbide semiconductor based upon a method of manufacturing and extracting silicon by grinding silicon carbide and silica sand (silica), mixing silicon carbide and silica sand (silica) with each other at predetermined ratio after cleaning them, housing them in a crucible for heating, heating them by a heating unit to make them react, oxidizing the silicon carbide with the silica sand (the silica), and further reducing them the silica sand (the silica) with the silicon carbide,
the method comprising the steps of:
forming a silicon carbide film by vapor phase epitaxy using active gas generated in heating for reaction for material; and
recovering the silicon carbide film.

2. The method of manufacturing a silicon carbide semiconductor according to claim 1, wherein the crucible for heating is made of silicon carbide.

3. The method of manufacturing a silicon carbide semiconductor according to claim 1, wherein, in heating for reaction, the crucible for heating is housed in a bell jar to enable heating for reaction in a decompressed condition.

4. The method of manufacturing a silicon carbide semiconductor according to claim 1, wherein:
the ratio of silicon carbide to silica sand (silica) is mainly 1:1;
the ratio is 10:1 at the maximum; and
the ratio is 1:10 at the minimum.

5. The method of manufacturing a silicon carbide semiconductor according to claim 1, wherein the crucible for heating is housed in a bell jar to enable heating for reaction in inert gas.

6. The method of manufacturing a silicon carbide semiconductor according to claim 1, wherein:
a crucible for recovery, the crucible for heating and a crucible for extraction are provided;
the crucible for heating and the crucible for extraction are formed in a cascaded configuration;
the crucible for recovery is installed sideways alongside the crucible for heating;
the crucible for recovery is formed with a lateral dimension longer; and
the crucible for recovery, the crucible for heating and the crucible for extraction are housed in a bell jar to facilitate reaction by heating.

7. The method of manufacturing silicon carbide according to claim 1, wherein the ratio of silicon carbide to silica sand (silica) is 2:1.

8. The method of manufacturing a silicon carbide semiconductor according to claim 3, wherein heating is performed to cause reaction in a condition in which an atmosphere is decompressed from 1 to 0.01 Pa.

9. A method of manufacturing a silicon carbide semiconductor based upon a method of manufacturing and extracting silicon by grinding silicon carbide and silica sand (silica), mixing silicon carbide and silica sand (silica) with each other at predetermined ratio after cleaning them, housing them in a crucible for heating, heating them by a heating unit to make them react, oxidizing the silicon carbide with the silica sand (the silica), and further reducing them the silica sand (the silica) with the silicon carbide,
the method comprising the steps of:
holding carbon in silicon in a condition of supersaturation by absorbing carbon from carbon monoxide and silicon from silicon monoxide in silicon fused liquid separately prepared using carbon monoxide and silicon monoxide in active gas generated in heating for material;
forming a silicon carbide film by epitaxial growth by slowly cooling; and
recovering the silicon carbide film.

10. A method of manufacturing silicon for simultaneously manufacturing silicon and silicon carbide based upon a method of manufacturing and extracting silicon by grinding silicon carbide and silica sand (silica), mixing silicon carbide and silica sand (silica) with each other at predetermined ratio after cleaning them, housing them in a crucible for heating, heating them by a heating unit to make them react, oxidizing the silicon carbide with the silica sand (the silica), and further reducing them the silica sand (the silica) with the silicon carbide,
the method comprising the steps of:
forming a silicon carbide film by vapor phase epitaxy using active gas generated in heating for reaction for material; and
recovering the silicon carbide film to produce silicon carbide.

11. A method of manufacturing silicon for simultaneously manufacturing silicon and silicon carbide based upon a method of manufacturing and extracting silicon by grinding silicon carbide and silica sand (silica), mixing silicon carbide and silica sand (silica) with each other at predetermined ratio after cleaning them, housing them in a crucible for heating, heating them by a heating unit to make them react, oxidizing the silicon carbide with the silica sand (the silica), and further reducing them the silica sand (the silica) with the silicon carbide,
the method comprising the steps of:
holding carbon in silicon in a condition of supersaturation by absorbing carbon from carbon monoxide and silicon from silicon monoxide in silicon fused liquid separately prepared using carbon monoxide and silicon monoxide in active gas generated in heating for material;
forming a silicon carbide film by epitaxial growth by slowly cooling; and
recovering the silicon carbide film to produce silicon carbide.

12. A silicon manufacturing system, comprising:
a crucible for heating that houses silicon carbide and silica sand (silica) respectively ground, cleaned and mixed;
a heating unit that heats the crucible for heating; and
a crucible for extraction that houses silicon extracted by oxidizing the silicon carbide with the silica sand (the silica), and further reducing the silica sand (the silica) with the silicon carbide.

13. The silicon manufacturing system according to claim 12, comprising:
a crucible for recovery;
the crucible for heating;
the crucible for extraction; and
a decompressing unit,
wherein: the crucibles are formed in a cascaded configuration; and
the crucibles and the decompressing unit are housed in a bell jar.

14. The silicon manufacturing system according to claim 12, comprising:
a crucible for recovery;
the crucible for heating;
the crucible for extraction; and
a decompressing unit,
wherein: the crucible for heating and the crucible for extraction are formed in a cascaded configuration;
the crucible for recovery is installed sideways alongside the crucible for heating;
the crucible for recovery is formed with a lateral dimension longer; and
the crucibles and the decompressing unit are housed in a bell jar.

15. A silicon carbide semiconductor manufacturing system, comprising:
a crucible for heating that houses silicon carbide and silica sand (silica) respectively ground, cleaned and mixed;
a heating unit that heats the crucible for heating;
a crucible for extraction that houses silicon extracted by oxidizing the silicon carbide with the silica sand (the silica), and further reducing the silica sand (the silica) with the silicon carbide;
a recovering unit that recovers active gas generated in heating for reaction; and
a crucible for recovery that recovers a silicon carbide film formed by using the recovered active gas for material.

16. The silicon carbide semiconductor manufacturing system according to claim 15, comprising:
the crucible for recovery;
the crucible for heating;
the crucible for extraction; and
a decompressing unit,
wherein: the crucibles are formed in a cascaded configuration; and
the crucibles and the decompressing unit are housed in a bell jar.

17. The silicon carbide semiconductor manufacturing system according to claim 15, comprising:
the crucible for recovery;
the crucible for heating;
the crucible for extraction; and
a decompressing unit,
wherein: the crucible for heating and the crucible for extraction are formed in a cascaded configuration;
the crucible for recovery is installed sideways alongside the crucible for heating;
the crucible for recovery is formed with a lateral dimension longer; and
the crucibles and the decompressing unit are housed in a bell jar.
